(19) United States
(12) Patent Application Publication
(10) Pub. No.: US 2015/0349226 A1
(43) Pub. Date: Dec. 3, 2015

(54) LIGHT-EMITTING ELEMENT AND METHOD OF MANUFACTURING THE SAME

(71) Applicant: TOYODA GOSEI CO., LTD., Kiyosu-shi (JP)

(72) Inventor: Hironao SHINOHARA, Chiba (JP)

(21) Appl. No.: 14/724,709

(22) Filed: May 28, 2015

(30) Foreign Application Priority Data
Jun. 2, 2014 (JP) 2014-114031

(51) Int. Cl. H01L 33/62; H01L 33/56

(52) U.S. Cl. CPC H01L 33/62; H01L 33/56

(57) ABSTRACT

A light-emitting element includes a bonding pad for connecting a bonding wire, and a coating film covering upper and side surfaces of the bonding pad. The coating film includes a mixture material including Au and one metal of Ta, Ti, Pt, Mo, Ni and W. A method of manufacturing a light-emitting element includes simultaneously sputtering Au and one metal of Ta, Ti, Pt, Mo, Ni and W on upper and side surfaces of a bonding pad by using the Au and the metal as a sputtering target so as to form thereon a coating film including a mixture material including Au and the metal.

The present application is based on Japanese patent application No.2014-114031 filed on Jun. 2, 2014, the entire contents of which are incorporated herein by reference.

### BACKGROUND OF THE INVENTION

1. Field Of The Invention

The invention relates to a light-emitting element and a method of manufacturing the light-emitting element.

2. Description Of The Related Art

A light-emitting element is known which has a bonding pad with Au on an outermost surface, a SiO₂ protective layer for protecting the surface of the bonding pad and a covering layer formed of Ta etc. and located between the bonding pad and the protective layer (see e.g. JP-A-2013-254893).

JP-A-2013-254893 discloses that the covering layer prevents deposition of low-molecular siloxane onto the bonding pad during die bonding process so as to control a decrease in bonding strength between the bonding pad and a bonding wire.

JP-A-2013-254893 also discloses that Au on the surface of the bonding pad may be alloyed with Ta etc. included in the covering layer.

### SUMMARY OF THE INVENTION

JP-A-2013-254893 reads that before wire bonding, the covering layer is removed by plasma etching for forming Au-Au bond between the bonding wire and the bonding pad. This may imply that the covering layer is not entirely alloyed therewith and Au is nearly empty on the surface of the covering layer.

If the etching of the covering layer prior to the wire bonding is eliminated from the manufacturing process of the light-emitting element in JP-A-2013-254893, it is possible to reduce the number of steps in the process so as to lower the manufacturing cost.

It is an object of the invention to provide a light-emitting element that is adapted to reduce the number of steps in the wire bonding process while preventing the deposition of the low-molecular siloxane onto the bonding pad during the die bonding process, as well as a method of manufacturing the light-emitting element.

(1) According to one embodiment of the invention, a light-emitting element comprises:

a bonding pad for connecting a bonding wire; and

a coating film covering upper and side surfaces of the bonding pad, wherein the coating film comprises a mixture material including Au and one metal of Ta, Ti, Pt, Mo, Ni and W.

In the above embodiment (1) of the invention, the following modifications and changes can be made.

(i) The mixture material includes Au and Ta.

(ii) A Ta concentration of the coating film is not less than 3.0 vol % and not more than 10.9 vol %.

(iii) The light-emitting element further comprises an emission wavelength of not less than 350 nm and not more than 514 nm.

(iv) The coating film has a thickness of not less than 100 Å and not more than 3000 Å.

(v) The light-emitting element further comprises a protective film comprising SiO2 and covering the side surface of the bonding pad via the coating film.

(vi) The Au and the metal are used as sputtering targets and are simultaneously sputtered on the upper and side surfaces of the bonding pad to form the coating film. (2) According to another embodiment of the invention, a method of manufacturing a light-emitting element comprises simultaneously sputtering Au and one metal of Ta, Ti, Pt, Mo, Ni and W on upper and side surfaces of a bonding pad by using the Au and the metal as a sputtering target so as to form thereon a coating film comprising a mixture material including Au and the metal.

In the above embodiment (2) of the invention, the following modifications and changes can be made.

(vii) The coating film comprising the mixture material including Au and Ta is formed by using the Au and Ta sputtering targets.

(viii) A Ta concentration of the coating film is not less than 3.0 vol % and not more than 10.9 vol %.

(ix) The coating film has a thickness of not less than 100 Å and not more than 3000 Å.

(x) The method further comprises covering the side surface of the bonding pad with a protective film including SiO2 via the coating film.

### Effects Of The Invention

According to one embodiment of the invention, a light-emitting element can be provided that is adapted to reduce the number of steps in the wire bonding process while preventing the deposition of the low-molecular siloxane onto the bonding pad during the die bonding process, as well as a method of manufacturing the light-emitting element.

### BRIEF DESCRIPTION OF THE DRAWINGS

Next, the present invention will be explained in more detail in conjunction with appended drawings, wherein:

FIG. 1 is a vertical cross-sectional view showing a light-emitting element 1 in an embodiment;

FIG. 2A is a vertical cross-sectional view showing a state in which a bonding wire is connected to a bonding pad and FIG. 2B is a vertical cross-sectional view showing Comparative Example in which a coating film formed of a metal such as Ta is used in place of a coating film of the embodiment;

FIG. 3 is a graph showing a relation between Ta concentration of the coating film and deposition rate of low-molecular siloxane when the coating film is formed of a mixture of Au with Ta;

FIG. 4 is a graph showing a relation between Ta concentration of the coating film and bonding strength of the bonding wire to the coating film when the coating film is formed of a mixture of Au with Ta;

FIG. 5A is a graph showing a relation between Ta concentration and reflectivity when the coating film is formed of a mixture of Au with Ta, FIG. 5B is a graph showing a relation between film thickness and reflectivity when the coating film is formed of a mixture of Au with Ta and FIG. 5C is a graph showing a relation between a distance from a sputtering target to a substrate during sputtering and reflectivity when the coating film is formed of a mixture of Au with Ta; and

FIG. 6A is a graph showing a relation between Ta concentration and reflectivity when light has a wavelength of 450 nm and FIG. 6B is a graph showing a relation between film thickness and reflectivity and a relation between a distance from the sputtering target to the substrate and reflectivity when light has a wavelength of 450 nm.

### DETAILED DESCRIPTION OF THE PREFERRED EMBODIMENTS

### Embodiment

### Configuration Of Light-Emitting Element

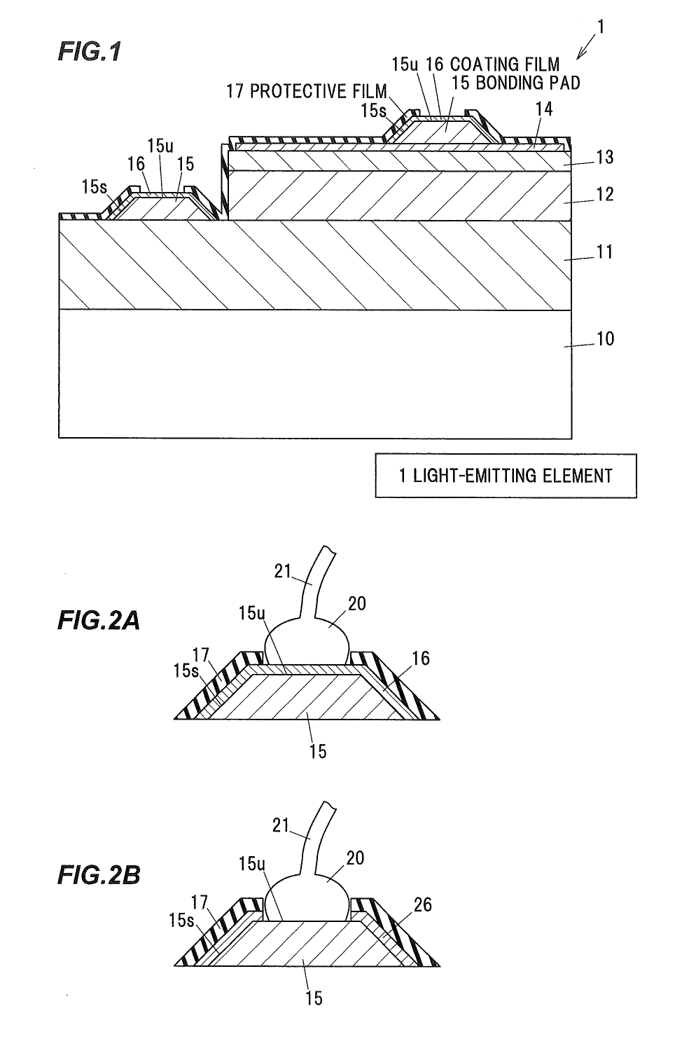

FIG. 1 is a vertical cross-sectional view showing the light-emitting element 1 in the embodiment.

The light-emitting element 1 has a substrate 10, an n-type semiconductor layer 11 on the substrate 10, a light-emitting layer 12 on the n-type semiconductor layer 11, a p-type semiconductor layer 13 on the light-emitting layer 12, a transparent electrode layer 14 on the p-type semiconductor layer 13, bonding pads 15 on the transparent electrode layer 14 and the n-type semiconductor layer 11, coating films 16 each covering an upper surface 15u and a side surface 15s of the bonding pad 15, and a protective film 17 covering the side surfaces of the bonding pads 15 via the coating films 16.

The light-emitting element 1 is, e.g., an LED chip or a laser diode, etc., and is powered through bonding wires connected to the bonding pads 15.

The substrate 10 is, e.g., a sapphire substrate.

Each of the n-type semiconductor layer 11, the light-emitting layer 12 and the p-type semiconductor layer 13 is formed of, e.g., a group-III nitride compound semiconductor. The group-III nitride compound semiconductor is, e.g., a quaternary group-III nitride compound semiconductor represented by AlₓGa_{y}In_{1-x-y}N (0≦x≦1, 0≦y≦1, 0≦x+y≦1).

The n-type semiconductor layer 11 has a laminated structure composed of, e.g., an n-type contact layer, an n-type ESD layer and an n-type cladding layer each of which contains an n-type dopant such as Si.

The light-emitting layer 12 has a multiple quantum well structure including, e.g., plural well layers and plural barrier layers. The well layers are formed of, e.g., InGaN and the barrier layers are formed of, e.g., GaN, InGaN or AlGaN.

The p-type semiconductor layer 13 has a laminated structure composed of, e.g., a p-type cladding layer and a p-type contact layer each of which contains a p-type dopant such as Mg.

The n-type semiconductor layer 11, the light-emitting layer 12 and the p-type semiconductor layer 13 are formed by epitaxially growing a crystal on the substrate 10 using, e.g., a metal organic chemical vapor deposition (MOCVD) method, a molecular beam epitaxy (MBE) method or a halide vapor phase epitaxy (HYPE) method. The positions of the n-type semiconductor layer 11 and the p-type semiconductor layer 13 may be reversed.

The transparent electrode layer 14 is a transparent layer formed of ITO (Sn-doped In₂O₃), etc., and allows the current flowing from the bonding pad 15 to be evenly diffused in the p-type semiconductor layer 13. The transparent electrode layer 14 is formed by, e.g., a vacuum deposition method, a sputtering method, a CVD method or a sol-gel method.

The bonding pad 15 is an electrode having an Au layer as the outermost surface to be connected to a bonding wire and has, e.g., a Ta/Pt/Au laminated structure. Light is emitted from the light-emitting layer 12 when a voltage is applied between the n-type semiconductor layer 11 and the p-type semiconductor layer 13 through the bonding pads 15. The bonding pad 15 can be formed by a sputtering method, etc.

The coating film 16 is formed of a mixture of Au with at least one type of metal selected from the group consisting of Ta, Ti, Pt, Mo, Ni and W.

By the coating film 16, low-molecular siloxane contained in a die bonding adhesive formed of a silicone-based resin is prevented from depositing on a surface of the bonding pad 15 during a die bonding process to fix the light-emitting element 1 to a supporting substrate or a lead frame.

The low-molecular siloxane evaporates from the adhesive mainly during heating process to cure the adhesive. The low-molecular siloxane is likely to deposit on Au. The low-molecular siloxane deposited on the surface of the bonding pad 15 decreases bonding strength between a bonding wire and the bonding pad 15.

The low-molecular siloxane has a low affinity for Ta, Ti, Pt, Mo, Ni or W contained in the coating film 16 and is less likely to deposit on the coating film 16 containing such metal(s).

In addition, the coating film 16 improves adhesion between the bonding pad 15 and the protective film 17. The function of the coating film 16 as an adhesive layer is importance since the protective film 17, particularly when formed of SiO₂, has low adhesion to the Au layer on the surface of the bonding pad 15 and is likely to come off

For forming the coating film 16, Au and the metal such as Ta are used as sputtering targets and are simultaneously sputtered on the upper surface 15u and the side surface 15s of the bonding pad 15. Thus, the entire coating film 16 is formed of a mixture of Au with the metal such as Ta.

The thickness of the coating film 16 is preferably not less than 100 Å (10 nm). When the thickness is not less than 100 Å, it is possible to effectively prevent deposition of the low-molecular siloxane on the surface of the bonding pad 15 during the die bonding process.

The thickness of the coating film 16 is preferably not more than 3000 Å (300 nm). It is because further improvement in the above-mentioned effects (prevention of deposition of the low-molecular siloxane on the bonding pad 15 and enhancement of adhesion between the bonding pad 15 and the protective film 17) is not obtained even if the thickness is increased to more than 3000 Å and it is thus not worth spending longer time for film formation.

When the coating film 16 is formed of a mixture of Au with Ta, a Ta concentration is preferably not less than 3.0 vol %. When the Ta concentration is not less than 3.0 vol %, it is possible to almost completely prevent deposition of the low-molecular siloxane on the bonding pad 15 during the die bonding process as long as the coating film 16 has a sufficient thickness (not less than 100 Å).

When the coating film 16 is formed of the mixture of Au with Ta, it is preferable that the Ta concentration be also not more than 10.9 vol %. When the Ta concentration is not more than 10.9 vol %, the reflectivity of the coating film 16 to reflect light emitted from the light-emitting element 1 is higher than that of an Au film with Ta concentration of 0% as long as the light emitted from the light-emitting element 1 has an emission wavelength of, e.g., not less than 350 nm and not more than 514 nm. The coating film 16 effectively reflects e.g. light which is emitted from the light-emitting element 1, is reflected at an interface between a sealing resin sealing the light-emitting element 1 and the external air and then returns toward the light-emitting element 1. As a result, light extraction efficiency of the package can be improved.

The protective film 17 prevents the bonding pad 15 from coming off when a lateral force is applied to the bonding pad 15 during the wire bonding process. The protective film 17 is formed of SiO₂, etc.

The protective film 17 can cover the entire surface of the light-emitting element 1 except a region above the upper surfaces 15u of the bonding pads 15, as shown in FIG. 1.

FIG. 2A is a vertical cross-sectional view showing a state in which a bonding wire 21 is connected to the bonding pad 15. FIG. 2B is a vertical cross-sectional view showing Comparative Example in which a coating film 26 formed of a metal such as Ta is used in place of the coating film 16.

The coating film 26 is formed of a metal having a low affinity for the low-molecular siloxane, such as Ta. Thus, both the coating film 16 shown in FIG. 2A and the coating film 26 shown in FIG. 2B can prevent deposition of the low-molecular siloxane on the bonding pad 15 during the bonding process.

However, since the coating film 26 does not contain Au, the coating film 26 on the upper surface 15u of the bonding pad 15 needs to be removed by etching before wire bonding as shown in FIG. 2B in order to form Au-Au bond between the bonding pad 15 and a ball 20 at a tip of the bonding wire 21.

Au contained in the Au layer on the surface of the bonding pad 15 could react with the metal contained in the coating film 26 to form an alloy. However, it is highly unlikely that Au at a concentration sufficient to form Au-Au bond between the ball 20 and the coating film 26 would reach the surface of the coating film 26. It is considered that Au can be present only in a very shallow region of the coating film 26 on the bonding pad 15 side especially when the coating film 26 is formed of a metal less likely to be thermally diffused, such as Ta.

On the other hand, Au is contained entirely in the coating film 16 of the present embodiment at a sufficient concentration and Au-Au bond is formed between the coating film 16 and the ball 20. Therefore, Au-Au bond between the bonding pad 15 and the ball 20 can be formed without removing the coating film 16 as shown in FIG. 2A and it is thus possible to eliminate an etching process.

### Evaluation Of Deposition Rate Of Siloxane

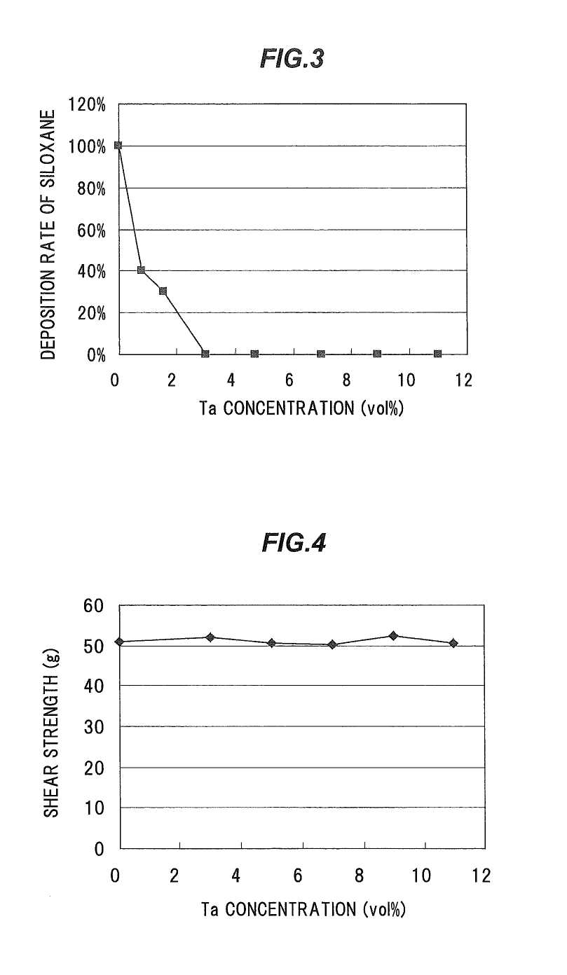

FIG. 3 is a graph showing a relation between Ta concentration of the coating film 16 and deposition rate of low-molecular siloxane when the coating film 16 is formed of a mixture of Au with Ta. In FIG. 3, the horizontal axis indicates Ta concentration (vol %) of the coating film 16 and the vertical axis indicates deposition rate (%)of siloxane.

The deposition rate of low-molecular siloxane was evaluated as follows. Firstly, the light-emitting element 1 was mounted on a ceramic substrate using a die-attach paste (adhesive) formed of silicone (die bonding process) and the die-attach paste was further applied to the edge of the ceramic substrate. Then, the ceramic substrate was heated in an oven at 150° C. for two hours to cure the die-attach paste. The rate of the low-molecular siloxane deposited on the bonding pad 15, i.e., on the coating film 16, after these steps was defined as the deposition rate of low-molecular siloxane.

Regardless of Ta concentration, all coating films 16 had a thickness of 2000 Å.

FIG. 3 shows that the deposition rate of low-molecular siloxane on the bonding pad 15 is substantially zero when the Ta concentration of the coating film 16 is not less than 3.0 vol %.

### Bonding Strength Evaluation For Bonding Wire

FIG. 4 is a graph showing a relation between Ta concentration of the coating film 16 and bonding strength of the bonding wire 21 to the coating film 16 when the coating film is formed of a mixture of Au with Ta. In FIG. 4, the horizontal axis indicates Ta concentration (vol %) of the coating film 16 and the vertical axis indicates shear strength (g) showing bonding strength of the bonding wire 21 to the coating film 16.

The bonding strength of the bonding wire was evaluated as follows. Firstly, the bonding wire 21 was bonded to the upper surface 15u of the bonding pad 15 via the coating film 16. Then, a horizontal force is applied to the ball 20 at a tip of the bonding wire 21 by a shear tool attached to a load sensor to measure a load value when the ball 20 was broken. The load value when the ball 20 was broken was defined as shear strength.

Regardless of Ta concentration, all coating films 16 had a thickness of 2000 Å.

As shown in FIG. 4, all coating films 16 have shear strength comparable to that of the Au film (Ta concentration of 0 vol %). This shows that, as long as the Ta concentration is not more than 10.9 vol %, Au-Au bond with sufficient strength is formed between the coating film 16 and the bonding wire 21 and the bonding strength therebetween is as good as that between the Au film and a bonding wire.

### Reflectivity Evaluation For Coating Film

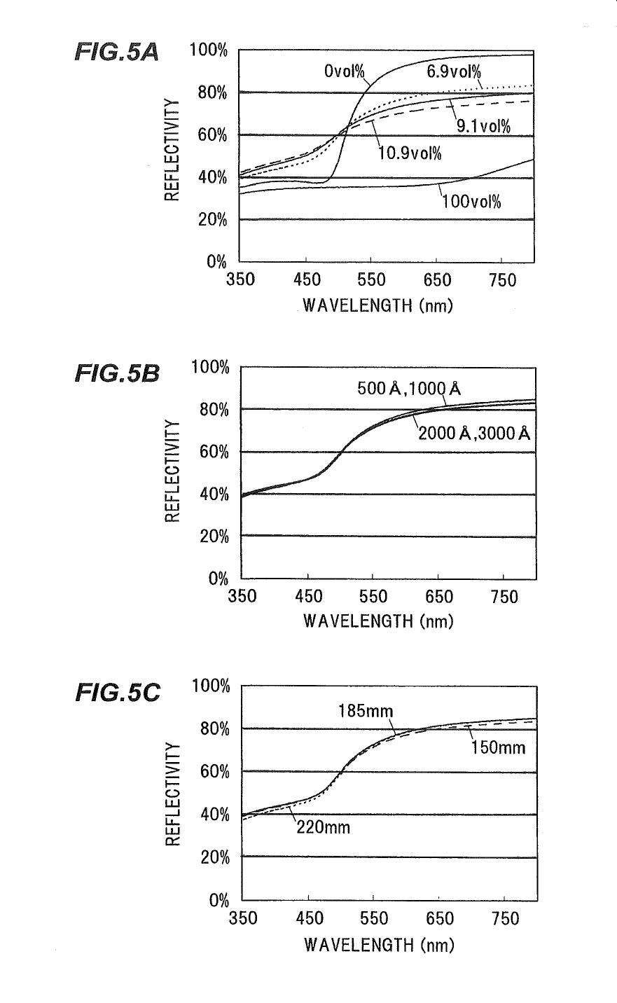

FIG. 5A is a graph showing a relation between Ta concentration and reflectivity when the coating film 16 is formed of a mixture of Au with Ta. In FIG. 5A, the horizontal axis indicates wavelength (nm) of light to be reflected and the vertical axis indicates reflectivity (%).

FIG. 5A shows measurement data of three coating films 16 respectively having Ta concentration of 6.9 vol %, 9.1 vol % and 10.9 vol % and also shows measurement data of an Au film (Ta concentration of 0 vol %) and a Ta film (Ta concentration of 100 vol %) as Comparative Example. All of these films have a thickness of 2000 Å.

FIG. 5A shows that reflectivity of the coating film 16 depends on the Ta concentration. Specifically, the three coating films 16 have higher reflectivity than the Au film in a wavelength range of not less than 350 nm and not more than 514 nm. Also, the three coating films 16 have higher reflectivity than the Ta film in a wavelength range of not less than 350 nm and not more than 800 nm.

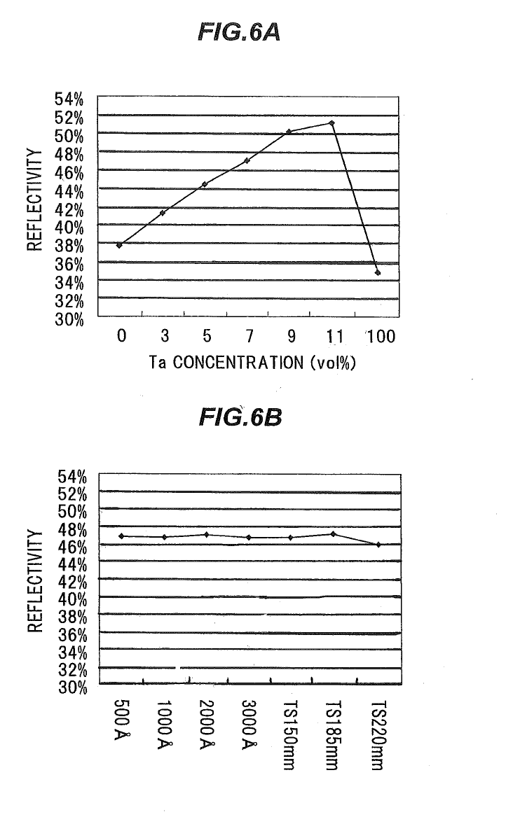

FIG. 6A is a graph showing a relation between Ta concentration and reflectivity when light has a wavelength of 450 nm. FIG. 6A shows data extracted from FIG. 5A.

FIG. 6A shows that, when light has a wavelength of 450 nm, reflectivity increases with an increase in Ta concentration of the coating film 16 up to 10.9 vol % and then sharply decreases toward 100 vol %.

FIG. 5B is a graph showing a relation between film thickness and reflectivity when the coating film 16 is formed of a mixture of Au with Ta. In FIG. 5B, the horizontal axis indicates wavelength (nm) of light to be reflected and the vertical axis indicates reflectivity (%).

FIG. 5B shows measurement data of four coating films 16 respectively having thicknesses of 500 Å, 1000 Å, 2000 Å and 3000 Å. All of these films have a Ta concentration of 6.9 vol %.

FIG. 5C is a graph showing a relation between a distance from a sputtering target to a substrate during sputtering and reflectivity when the coating film 16 is formed of a mixture of Au with Ta. In FIG. 5C, the horizontal axis indicates wavelength (nm) of light to be reflected and the vertical axis indicates reflectivity (%).

FIG. 5C shows measurement data of three coating films 16 formed by sputtering from a sputtering target to the substrate 10 at distances respectively of 150 nm, 185 nm and 220 nm. All of these films have a Ta concentration of 6.9 vol % and a thickness of 2000 Å.

FIGS. 5B and 5C show that reflectivity of the coating film 16 virtually does not depend on the film thickness and the distance between the sputtering target and the substrate 10.

FIG. 6B is a graph showing a relation between film thickness and reflectivity and a relation between a distance from the sputtering target to the substrate 10 and reflectivity when light has a wavelength of 450 nm. FIG. 6B shows data extracted from FIGS. 5B and 5C. In FIG. 6B, “TS” means a distance between the sputtering target and the substrate 10.

FIG. 6B shows that reflectivity of the coating film 16 virtually does not depend on the film thickness and the distance between the sputtering target and the substrate 10 when light has a wavelength of 450 nm.

### Effects Of The Embodiment

In the embodiment, by covering the upper surface 15u and side surface 15s of the bonding pad 15 with the coating film 16 formed of a material as a mixture of Au with a metal such as Ta, it is possible to prevent low-molecular siloxane from depositing on the bonding pad 15 during the die bonding process. In addition, since the bonding wire is bonded to the coating film 16 with sufficient bonding strength during the wire bonding process, removal of the coating film 16 to directly bond the bonding wire to the bonding pad 15 is not required and it is thus possible to eliminate an etching process.

Although the embodiment of the invention has been described above, the invention is not intended to be limited to the embodiment and the various kinds of modifications can be implemented without departing from the gist of the invention.

In addition, the invention according to claims is not to be limited to the embodiment. Further, all combinations of the features described in the embodiment are not needed so as to solve the problem of the invention.

What is claimed is:

1. A light-emitting element, comprising:
a bonding pad for connecting a bonding wire; and
a coating film covering upper and side surfaces of the bonding pad,
wherein the coating film comprises a mixture material including Au and one metal of Ta, Ti, Pt, Mo, Ni and W.

2. The light-emitting element according to claim 1, the mixture material includes Au and Ta.

3. The light-emitting element according to claim 2, wherein a Ta concentration of the coating film is not less than 3.0 vol % and not more than 10.9 vol %.

4. The light-emitting element according to claim 2, further comprising an emission wavelength of not less than 350 nm and not more than 514 nm.

5. The light-emitting element according to claim 1, wherein the coating film has a thickness of not less than 100 Å and not more than 3000 Å.

6. The light-emitting element according to claim 1, further comprising a protective film comprising SiO2 and covering the side surface of the bonding pad via the coating film.

7. The light-emitting element according to claim 1, wherein the Au and the metal are used as sputtering targets and are simultaneously sputtered on the upper and side surfaces of the bonding pad to form the coating film.

8. A method of manufacturing a light-emitting element, comprising simultaneously sputtering Au and one metal of Ta, Ti, Pt, Mo, Ni and W on upper and side surfaces of a bonding pad by using the Au and the metal as a sputtering target so as to form thereon a coating film comprising a mixture material including Au and the metal.

9. The method according to claim 8, wherein the coating film comprising the mixture material including Au and Ta is formed by using the Au and Ta sputtering targets.

10. The method according to claim 9, wherein a Ta concentration of the coating film is not less than 3.0 vol % and not more than 10.9 vol %.

11. The method according to claim 8, wherein the coating film has a thickness of not less than 100 Å and not more than 3000 Å.

12. The method according to claim 8, further comprising covering the side surface of the bonding pad with a protective film including SiO₂ via the coating film.
